(19) United States
(12) Patent Application Publication
(10) Pub. No.: US 2026/0090346 A1
(43) Pub. Date: Mar. 26, 2026

(54) SEMICONDUCTOR STRUCTURE AND FABRICATION METHOD THEREOF

(71) Applicant: UNITED MICROELECTRONICS CORP., Hsin-Chu City (TW)

(72) Inventors: Da-Jun Lin, Kaohsiung City (TW); Yi-An Shih, Changhua County (TW); Bin-Siang Tsai, Changhua County (TW); Fu-Yu Tsai, Tainan City (TW)

(73) Assignee: UNITED MICROELECTRONICS CORP., Hsin-Chu City (TW)

(21) Appl. No.: 18/919,463

(22) Filed: Oct. 18, 2024

(30) Foreign Application Priority Data
Sep. 26, 2024 (TW) 113136603

(51) Int. Cl. H01L 21/762; H01L 21/768; H01L 23/48; H01L 27/12

(52) U.S. Cl. CPC H10P 90/1908; H10D 87/00; H10W 10/061; H10W 10/181; H10W 20/023; H10W 20/20

(57) ABSTRACT

A semiconductor structure includes a SOI substrate having a base substrate, a buried oxide layer on the base substrate, and a device layer on the buried oxide layer. A circuit element is disposed on the device layer and surrounded by a trench isolation region in the SOI substrate. A buried power rail is embedded in the trench isolation region and the buried oxide layer. The buried power rail is isolated from the device layer by the buried oxide layer and a trench-filling oxide in the trench isolation region.

### BACKGROUND OF THE INVENTION

### 1. Field of the Invention

The present invention relates to the field of semiconductor technology, and in particular, to an improved silicon-on-insulation (SOI) semiconductor structure and a manufacturing method thereof.

### 2. Description of the Prior Art

Backside Power Delivery (BPD) technology is one of the key technologies for realizing sub-3nm node chip production. BPD eliminates the need for signal and power lines to compete for interconnect resources on the front side of the wafer. Instead, as the name suggests, power signals are transmitted from the backside of the wafer, leaving only signal transmission via front-side interconnects. BPD also allows for optimal manufacturing of these different metal layers, including wider lines for Vdd and Vss signal transmission and finer lines for carrying high-frequency signals. Despite these advantages, BPD still faces numerous process challenges that need to be overcome.

### SUMMARY OF THE INVENTION

It is one object of the present invention to provide an improved silicon-on-insulator (SOI) semiconductor structure and a manufacturing method thereof to solve the deficiencies or shortcomings of the existing technology.

One aspect of the invention provides a semiconductor structure including a silicon-on-insulator (SOI) substrate having a base substrate, a buried oxide layer on the base substrate, and a device layer on the buried oxide layer; a circuit element disposed on the device layer and surrounded by a trench isolation region in the SOI substrate; and a buried power rail embedded in the trench isolation region and the buried oxide layer, wherein the buried power rail is isolated from the device layer by the buried oxide layer and a trench-filling oxide in the trench isolation region.

According to some embodiments, the buried power rail is electrically connected to a through substrate via in the base substrate.

According to some embodiments, the buried power rail and the through substrate via are integrated formed by copper.

According to some embodiments, the through substrate via is isolated from the base substrate by an oxide liner.

According to some embodiments, the circuit element is a transistor element.

According to some embodiments, the buried oxide layer has a thickness of 2000 angstroms.

According to some embodiments, the device layer is a silicon epitaxial layer.

According to some embodiments, the silicon epitaxial layer has a thickness of 1400 angstroms.

According to some embodiments, the base substrate is a silicon substrate.

According to some embodiments, the silicon substrate has a thickness of 7-100 micrometers.

Another aspect of the invention provides a method for forming a semiconductor structure. A silicon-on-insulator (SOI) substrate is provided. The SOI substrate includes a base substrate, a buried oxide layer on the base substrate, and a device layer on the buried oxide layer. A circuit element is formed on the device layer. The circuit element is surrounded by a trench isolation region in the SOI substrate. A buried power rail is formed in the trench isolation region and the buried oxide layer. The buried power rail is isolated from the device layer by the buried oxide layer and a trench-filling oxide in the trench isolation region.

According to some embodiments, the buried power rail is electrically connected to a through substrate via in the base substrate.

According to some embodiments, the buried power rail and the through substrate via are integrated formed by copper.

According to some embodiments, the through substrate via is isolated from the base substrate by an oxide liner.

According to some embodiments, the circuit element is a transistor element.

According to some embodiments, the buried oxide layer has a thickness of 2000 angstroms.

According to some embodiments, the device layer is a silicon epitaxial layer.

According to some embodiments, the silicon epitaxial layer has a thickness of 1400 angstroms.

According to some embodiments, the base substrate is a silicon substrate.

According to some embodiments, the silicon substrate has a thickness of 7-100 micrometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 11 are schematic diagrams showing a method for forming a semiconductor structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

FIG. 1 to FIG. 11 are schematic diagrams showing a method for forming a semiconductor structure according to an embodiment of the present invention. As shown in FIG. 1, first, a silicon-on-insulator (SOI) substrate 100 is provided. The SOI substrate 100 includes a base substrate 111, a buried oxide layer 112 located on the base substrate 111, and a device layer 113 located on the buried oxide layer 112. According to an embodiment of the present invention, the base substrate 111 is, for example, a silicon substrate, and the thickness of the substrate 111 is, for example, 7-100 micrometers. According to an embodiment of the present invention, the thickness of the buried oxide layer 112 is, for example, 2000 angstroms. According to an embodiment of the present invention, the device layer 113 is, for example, an epitaxial silicon layer, and the thickness of the device layer 113 is, for example, 1400 angstroms.

Subsequently, shallow trench isolation (STI) process is performed to form a trench isolation region IT and a plurality of active regions 110 surrounded and isolated by the trench isolation region IT in the device layer 113. According to an embodiment of the present invention, the trench isolation region IT includes a trench-filling oxide 120, such as, but not limited to, silicon dioxide.

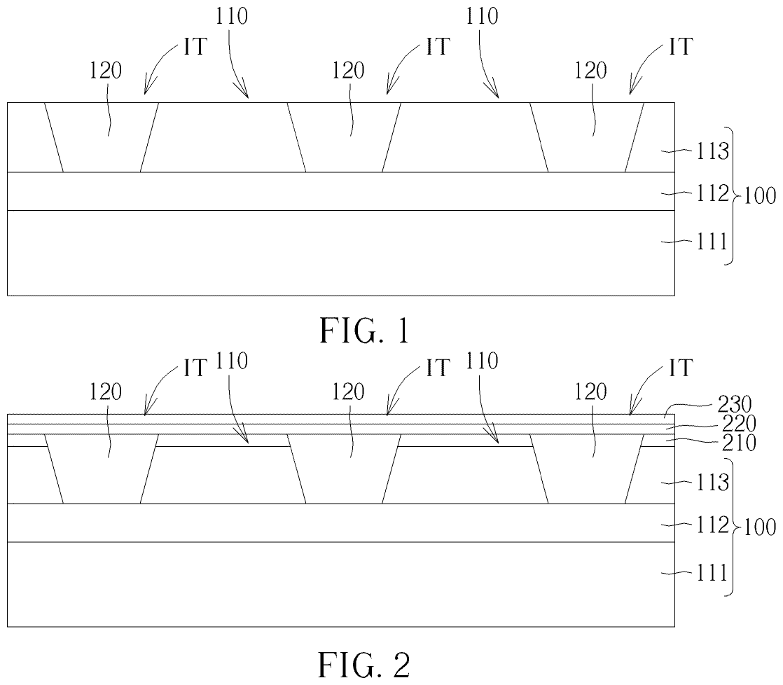

As shown in FIG. 2, an oxidation process is then performed to form a gate oxide layer 210 on the active region 110. A deposition process, such as a chemical vapor deposition (CVD) process, is then performed to deposit a high-k material layer 220 and a barrier layer 230 on the SOI substrate 100. According to an embodiment of the present invention, the high-k material layer 220 is, for example, but not limited to, HfO₂. According to an embodiment of the present invention, the barrier layer 230 is, for example, but not limited to, TiN.

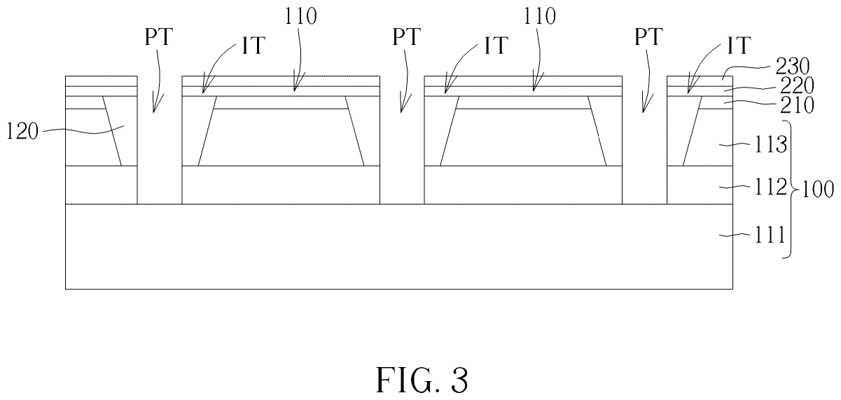

As shown in FIG. 3, a lithography process and an etching process are then performed to form a trench PT that penetrates the barrier layer 230, the high-k material layer 220, the trench-filling oxide 120, and the buried oxide layer 112. According to an embodiment of the present invention, the trench PT is located in the trench isolation region IT, and the bottom thereof exposes a portion of the base substrate 111.

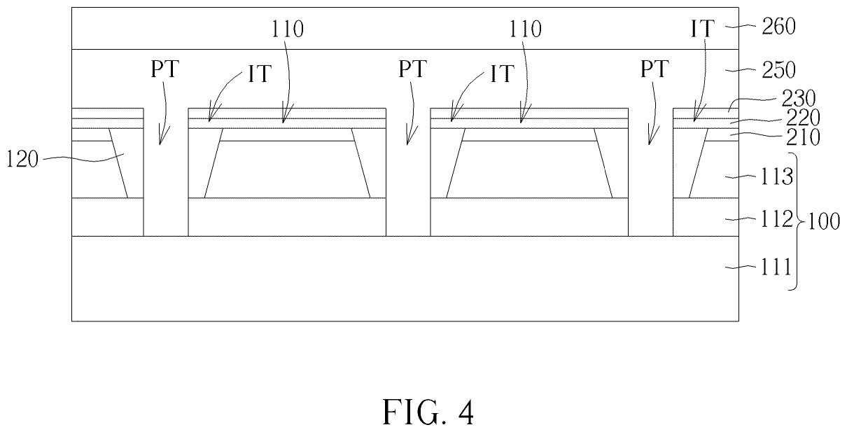

As shown in FIG. 4, a deposition process is then performed to deposit a polysilicon layer 250 on the SOI substrate 100, and the polysilicon layer 250 fills the trench PT. A deposition process, such as a chemical vapor deposition (CVD) process, is then performed to form a hard mask layer 260 on the polysilicon layer 250. According to an embodiment of the present invention, the hard mask layer 260 is, for example, but not limited to, a silicon nitride layer.

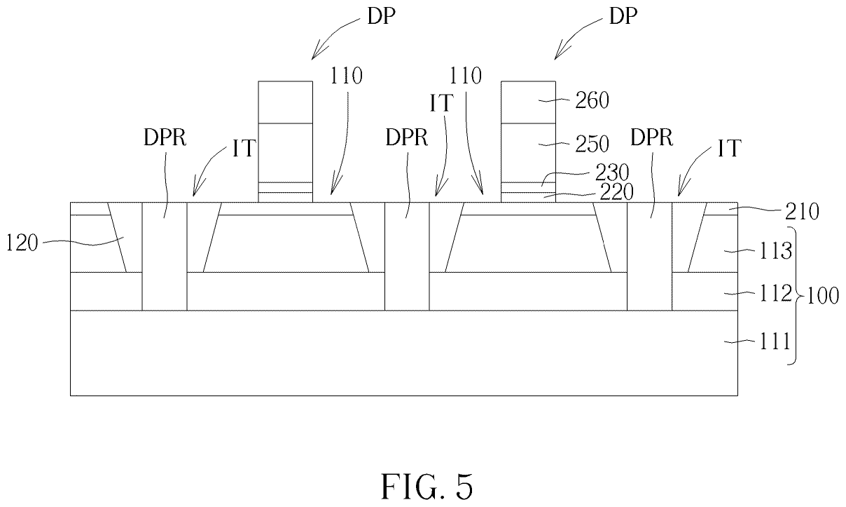

Subsequently, as shown in FIG. 5, a photolithography process and an etching process are performed to pattern the hard mask layer 260, the polysilicon layer 250, the barrier layer 230, and the high-k material layer 220 into a dummy gate structure DP, and simultaneously, a dummy polysilicon rail DPR is formed in the trench PT. According to an embodiment of the present invention, the dummy polysilicon rail DPR extends downward into the trench-filling oxide 120 and the buried oxide layer 112, and directly contacts the base substrate 111.

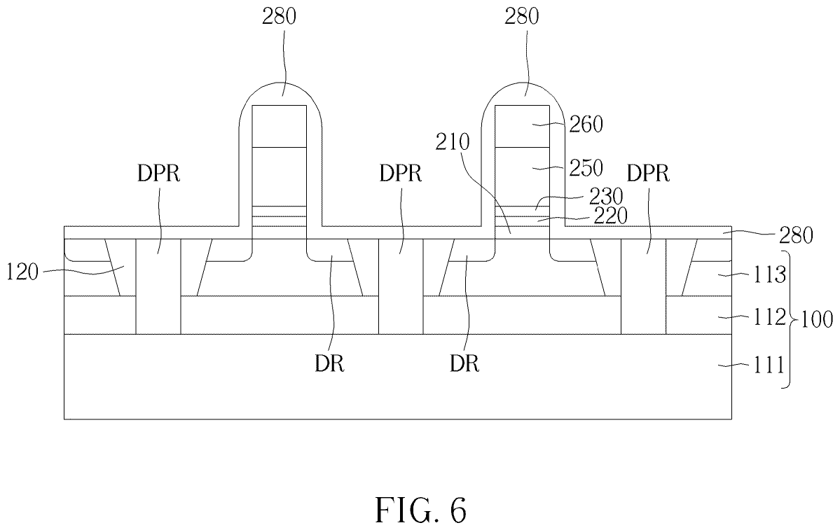

As shown in FIG. 6, an ion implantation process is then performed to form a doped region DR in the active region 110. According to an embodiment of the present invention, the doped region DR may be, for example, an N-type or P-type doped region. Subsequently, a deposition process, such as a chemical vapor deposition (CVD) process, is performed to deposit an etch stop layer 280, such as a silicon nitride layer, on the SOI substrate 100 in a blanket manner. According to an embodiment of the present invention, the etch stop layer 280 is conformally deposited on the trench isolation region IT, the dummy polysilicon rail DPR, and the dummy gate structure DP.

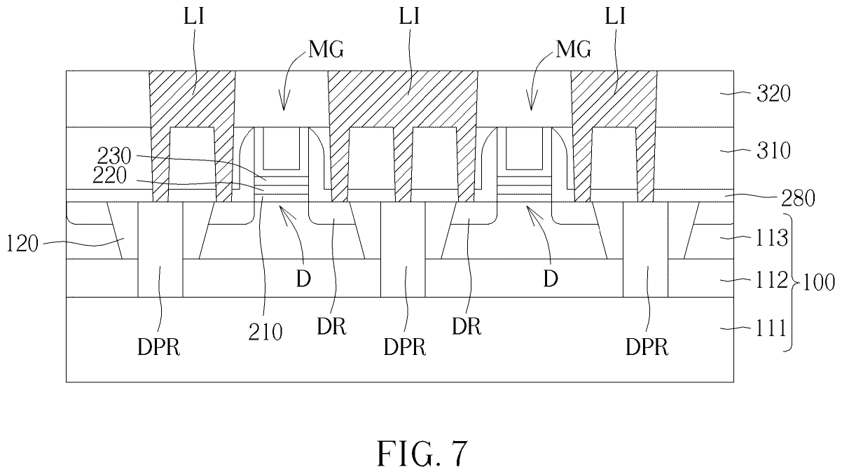

As shown in FIG. 7, a deposition process, such as a chemical vapor deposition (CVD) process, is then performed to deposit a dielectric layer 310 on the SOI substrate 100 in a blanket manner, and then a replacement metal gate (RMG) process is performed to remove the dummy gate structure DP to form a gate trench. The gate trench is then filled with a work function metal and a low-resistance metal. A chemical mechanical polishing (CMP) process is then performed to form a metal gate MG. The metal gate MG and the doped region DR can constitute a circuit element D, such as a MOS transistor element. Subsequently, a dielectric layer 320 is deposited on the dielectric layer 310 and the metal gate MG. A metallization process is then performed to form an local interconnect LI in the dielectric layer 320 and the dielectric layer 310, which electrically connects the doped region DR and the dummy polysilicon rail DPR. According to an embodiment of the present invention, the dielectric layer 310 and the dielectric layer 320 may be a single dielectric layer or a combination of multiple dielectric layers stacked.

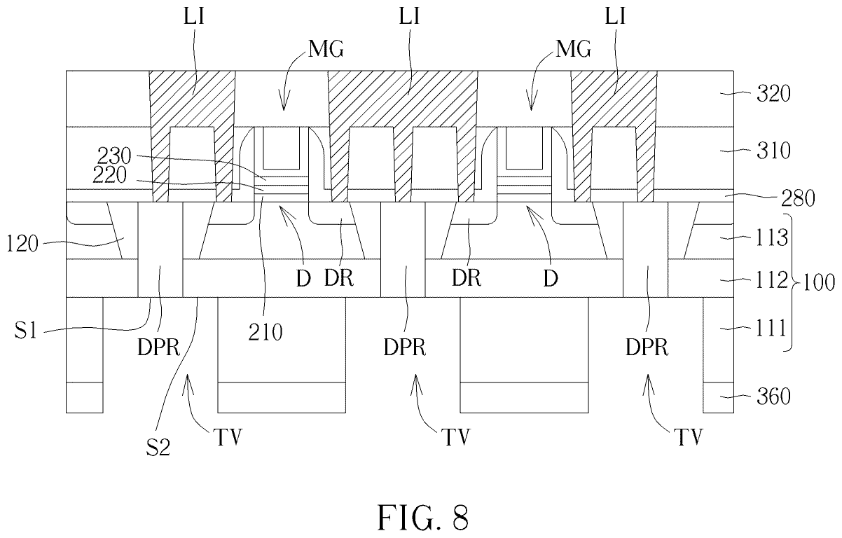

As shown in FIG. 8, a hard mask layer 360, such as a silicon oxide layer, is formed on the substrate 111. Through photolithography and etching processes, a through-via TV is formed in the hard mask layer 360 and the base substrate 111, exposing the bottom surface S1 of the dummy polysilicon rail DPR and part of the bottom surface S2 of the buried oxide layer 112.

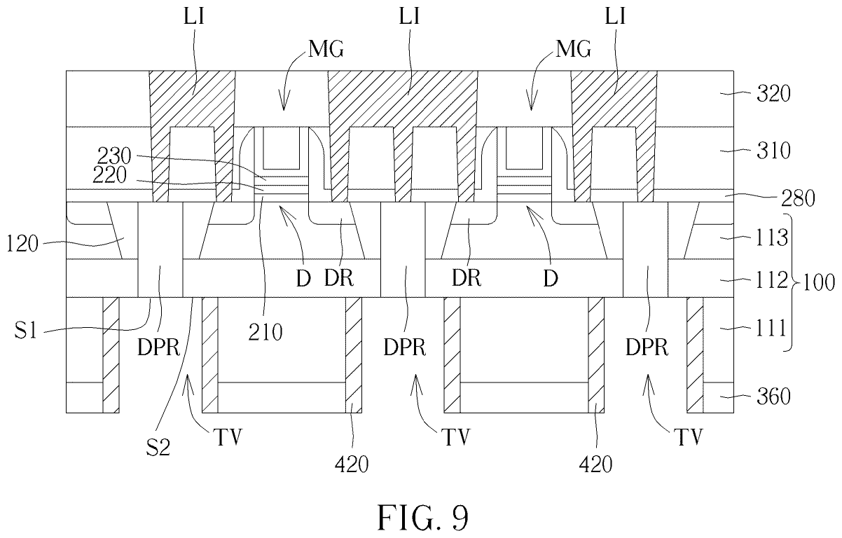

As shown in FIG. 9, a deposition process, such as chemical vapor deposition (CVD), is performed to conformally deposit an oxide liner layer 420, such as a silicon dioxide liner layer, inside the through-via TV and on the hard mask layer 360. Subsequently, an anisotropic dry etching process is performed to etch away the oxide liner layer 420 on the hard mask layer 360 and the bottom of the through-via TV, exposing the bottom surface S1 of the dummy polysilicon rail DPR.

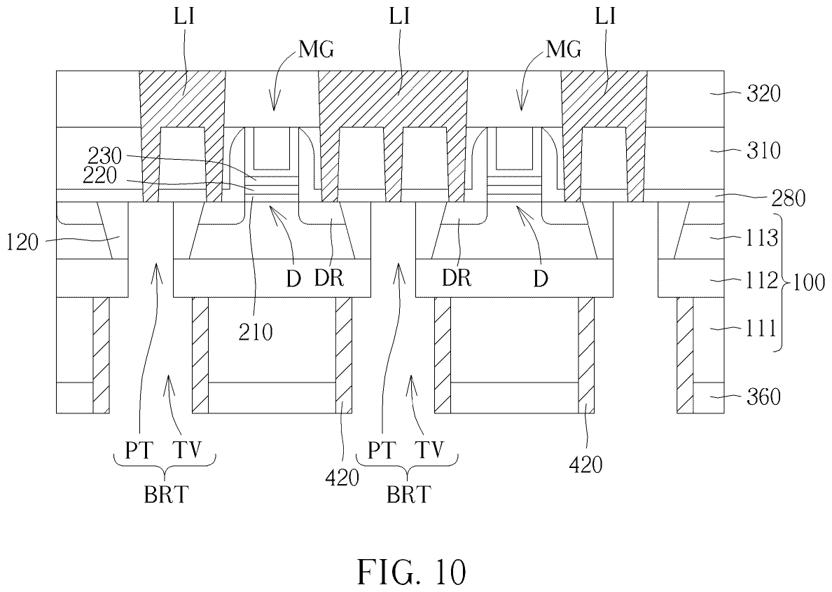

As shown in FIG. 10, an etching process is performed to completely remove the dummy polysilicon rail DPR through the through-via TV, so that the trench PT located in the trench isolation region IT and the through-via TV together form a back-side power rail trench BRT. At this point, part of the local interconnect LI and part of the etch stop layer 280 are exposed in the back-side power rail trench BRT.

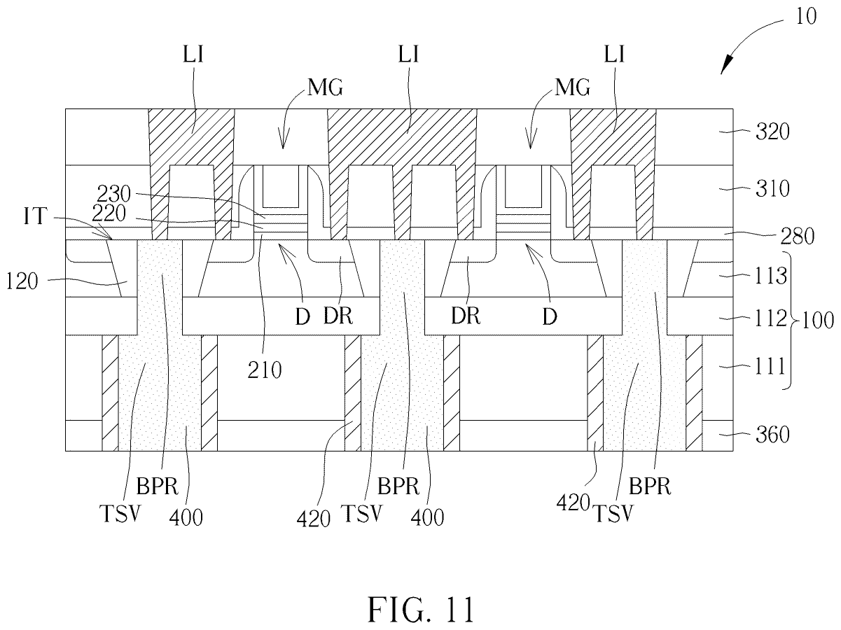

Next, as shown in FIG. 11, a metallization process is performed to fill the back-side power rail trench BRT with a conductive layer 400, such as a copper metal layer, forming a buried power rail BPR embedded in the trench isolation region IT and the buried oxide layer 112, and a through-substrate via TSV embedded in the base substrate 111, thus completing the semiconductor structure 10 of the present invention.

According to an embodiment of the present invention, the buried power rail BPR is electrically isolated from the device layer 113 through the buried oxide layer 112 and the trench-filling oxide 120 in the trench isolation region IT. According to an embodiment of the present invention, the buried power rail BPR is electrically connected to the through-substrate via TSV in the base substrate 111. According to an embodiment of the present invention, the buried power rail BPR and the through-substrate via TSV are integrally formed by using copper. According to an embodiment of the present invention, the through-substrate via TSV is electrically isolated from the base substrate 111 through the oxide liner layer 420.

Structurally, as shown in FIG. 11, the semiconductor structure 10 of this invention includes a silicon-on-insulator (SOI) substrate 100 including a base substrate 111, a buried oxide layer 112 located on the base substrate 111, and a device layer 113 located on the buried oxide layer 112; a circuit element D located on the device layer 113 and surrounded by a trench isolation region IT in the SOI substrate 100; and a buried power rail BPR embedded in the trench isolation region IT and the buried oxide layer 112. The buried power rail BPR is isolated from the device layer 113 through the buried oxide layer 112 and the trench-filling oxide 120 in the trench isolation region IT.

According to an embodiment of the present invention, the buried power rail BPR is electrically connected to the through-substrate via TSV in the base substrate 111. According to an embodiment of the present invention, the buried power rail BPR and the through-substrate via (TSV) are integrally formed by using copper. According to an embodiment of the present invention, the through-substrate via (TSV) is electrically isolated from the base substrate 111 through the oxide liner layer 420.

According to an embodiment of the present invention, the circuit element D is a transistor element.

According to an embodiment of the present invention, for example, the thickness of the buried oxide layer 112 is 2000 angstroms. According to an embodiment of the present invention, the device layer 113 is an epitaxial silicon layer, with a thickness of, for example, 1400 angstroms. According to an embodiment of the present invention, the base substrate 111 is a silicon substrate, with a thickness of, for example, 7-100 micrometers.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a silicon-on-insulator (SOI) substrate having a base substrate, a buried oxide layer on the base substrate, and a device layer on the buried oxide layer;
a circuit element disposed on the device layer and surrounded by a trench isolation region in the SOI substrate; and
a buried power rail embedded in the trench isolation region and the buried oxide layer, wherein the buried power rail is isolated from the device layer by the buried oxide layer and a trench-filling oxide in the trench isolation region.

2. The semiconductor structure according to claim 1, wherein the buried power rail is electrically connected to a through substrate via in the base substrate.

3. The semiconductor structure according to claim 2, wherein the buried power rail and the through substrate via are integrated formed by copper.

4. The semiconductor structure according to claim 2, wherein the through substrate via is isolated from the base substrate by an oxide liner.

5. The semiconductor structure according to claim 1, wherein the circuit element is a transistor element.

6. The semiconductor structure according to claim 1, wherein the buried oxide layer has a thickness of 2000 angstroms.

7. The semiconductor structure according to claim 1, wherein the device layer is a silicon epitaxial layer.

8. The semiconductor structure according to claim 7, wherein the silicon epitaxial layer has a thickness of 1400 angstroms.

9. The semiconductor structure according to claim 1, wherein the base substrate is a silicon substrate.

10. The semiconductor structure according to claim 9, wherein the silicon substrate has a thickness of 7-100 micrometers.

11. A method for forming a semiconductor structure, comprising:
providing a silicon-on-insulator (SOI) substrate having a base substrate, a buried oxide layer on the base substrate, and a device layer on the buried oxide layer;
forming a circuit element on the device layer and surrounded by a trench isolation region in the SOI substrate; and
forming a buried power rail in the trench isolation region and the buried oxide layer, wherein the buried power rail is isolated from the device layer by the buried oxide layer and a trench-filling oxide in the trench isolation region.

12. The method according to claim 11, wherein the buried power rail is electrically connected to a through substrate via in the base substrate.

13. The method according to claim 12, wherein the buried power rail and the through substrate via are integrated formed by copper.

14. The method according to claim 12, wherein the through substrate via is isolated from the base substrate by an oxide liner.

15. The method according to claim 11, wherein the circuit element is a transistor element.

16. The method according to claim 11, wherein the buried oxide layer has a thickness of 2000 angstroms.

17. The method according to claim 11, wherein the device layer is a silicon epitaxial layer.

18. The method according to claim 17, wherein the silicon epitaxial layer has a thickness of 1400 angstroms.

19. The method according to claim 11, wherein the base substrate is a silicon substrate.

20. The method according to claim 19, wherein the silicon substrate has a thickness of 7-100 micrometers.
